(19) United States
(12) Patent Application Publication
(10) Pub. No.: US 2011/0202295 A1
(43) Pub. Date: Aug. 18, 2011

(54) CURRENT MEASURING DEVICE

(75) Inventors: Manabu TAMURA, Miyagi-Ken (JP); Masatoshi NOMURA, Miyagi-Ken (JP); Masaru KOISHI, Miyagi-Ken (JP)

(73) Assignee: ALPS GREEN DEVICES CO., LTD., Tokyo (JP)

(21) Appl. No.: 13/020,757

(22) Filed: Feb. 3, 2011

(30) Foreign Application Priority Data
Feb. 12, 2010 (JP) 2010-028994

(51) Int. Cl. G01R 19/00

(52) U.S. Cl. 702/64

(57) ABSTRACT

A current measuring device includes a conductor in which detection target current flows, at least two magnetic sensors that detect change of magnetic field generated when the detection target current flows in the conductor, and a calculation unit that calculates magnitude of the detection target current from an output of the magnetic sensor. At least two magnetic sensors are provided at different distances from the conductor, and the calculation unit acquires distances between the magnetic sensors and the conductor to calculate magnitude of the detection target current using the distances.

### CLAIM OF PRIORITY

This application claims benefit of Japanese Patent Application No. 2010-028994 filed on Feb. 12, 2010, which is hereby incorporated by reference.

### BACKGROUND OF THE INVENTION

1. Field of the Invention

The present invention relates to a current measuring device that measures magnitude of current of a conductor, and more particularly, to a current measuring device that detects current flowing in a conductor through a magnetic-electric conversion element.

2. Description of the Related Art

Recently, in the field of electric vehicles and solar batteries, handled current values have been increased according to high output and high performance of the electric vehicles and solar batteries, and current sensors measuring great direct current in a non-contact manner have been widely used. As such a current sensor, there is a sensor provided with a magnetic-electric conversion element detecting current flowing in a conductor as a detection target through change of magnetic field around the conductor (e.g., Japanese Unexamined Patent Application Publication No. 2008-151743).

The current sensor is provided with a bus bar in which current as a detection target flows, a shield plate provided around the bus bar, and a magnetic-electric conversion element provided at a position where magnetic flux density of magnetic field generated when current flows in the bus bar is minimal, between the bus bar and the shield plate. When the current as the detection target flows in the bus bar, change of magnetic field generated around the bus bar is converted into voltage by the magnetic-electric conversion element, and the voltage is output as a signal corresponding to magnitude of the current. The output signal from the magnetic-electric conversion element is amplified by an amplification circuit and is detected by a detection circuit, thereby detecting the magnitude of the current flowing in the bus bar.

In the current sensor, a distance between the magnetic-electric conversion element and a conductor as a detection target is changed by error of an installation position of the magnetic-electric conversion element at the producing time, or thermal expansion and contraction caused by heat emission of the device at the time of using the current sensor. When the distance between the magnetic-electric conversion element and the conductor is changed, the magnetic flux density of magnetic field detected by the magnetic-electric conversion element is changed, and there is a problem that detection error of magnitude of the current flowing in the conductor occurs. In the current sensor described in Japanese Unexamined Patent Application Publication No. 2008-151743, the magnetic-electric conversion element is provided in the vicinity of the position where the change of the magnetic flux density generated when the current flows is minimal, to reduce the detection error when the distance between the magnetic-electric conversion element and the conductor is changed.

However, in the current sensor described in Japanese Unexamined Patent Application Publication No. 2008-151743, since the magnetic-electric conversion element is provided in the vicinity of the position where the change of the magnetic flux density is minimal, there is a problem that detection sensitivity of the current sensor is decreased. Even when the magnetic-electric conversion element is provided in the vicinity of the position where the magnetic flux density is minimal, there is a problem that it is difficult to effectively reduce the detection error.

### SUMMARY OF THE INVENTION

An advantage of some aspects of the invention is to provide a current measuring device capable of correcting a distance between a conductor and a magnetic-electric conversion element and detecting detection target current with high sensitivity and high precision.

According to an aspect of the invention, there is provided a current measuring device including: a conductor in which detection target current flows; at least two magnetic sensors that detect change of magnetic field generated when the detection target current flows in the conductor; and a calculation unit that calculates magnitude of the detection target current from an output of the magnetic sensor, wherein at least two magnetic sensors are provided at different distances from the conductor, and the calculation unit acquires distances between the magnetic sensors and the conductor from the output of the magnetic sensor to calculate magnitude of the detection target current using the distances.

With such a configuration, since the magnetic field generated around the conductor when the current as the detection target flows in the conductor is detected by at least two magnetic sensors provided at different distances from the conductor, it is possible to obtain output signals with intensity corresponding to the distance difference. As described above, since it is possible to obtain the output signals with intensity corresponding to the distance difference from at least two magnetic sensors, it is possible to correct the distance between the magnetic sensors and the conductor using the signals. Accordingly, it is possible to correct the distance even when the distance between the magnetic sensor and the conductor is changed from a designed value, for example, by error of the dispositional position of the current measuring device at the producing time or thermal expansion of a constituent member of the current measuring device at the time of using the current measuring device. For this reason, it is possible to detect the current value with high sensitivity and high precision by calculating the detection target current using the distance between the magnetic sensor and the conductor after the correction.

In the current measuring device according to the aspect of the invention, it is preferable that the calculation unit calculates the magnitude of the detection target current by a calculation process based on the following formula (1) using the output of the magnetic sensor:

H=μoI/2πr Formula (1),

where μo indicates vacuum magnetic permeability, H indicates magnetic field intensity, and r indicates a distance between a center P of the conductor and the magnetic sensor.

With such a configuration, the current value is calculated using the output signals of at least two magnetic sensors provided at the different distances from the conductor using the formula (1), and thus it is possible to detect the current value of the detection target current with high precision. Even when the magnetic sensor is provided in the vicinity of the conductor, it is possible to correct the distance between the magnetic sensor and the conductor, and thus it is possible to realize the high-sensitivity current measuring device.

In the current measuring device according to the aspect of the invention, it is preferable that at least two magnetic sensors are provided in the same package material. With such a configuration, it is possible to reduce the size of the current detecting device.

In the current measuring device according to the aspect of the invention, it is preferable to further include another magnetic sensor opposed to the magnetic sensor with the conductor interposed therebetween, wherein the calculation unit detects magnitude of disturbance noise from a difference value between an output of the magnetic sensor and an output of the other magnetic sensor and calculates the detection target current using the magnitude of the disturbance noise.

With such a configuration, since the calculation process is performed using the difference value between the output signal of the magnetic sensor and the output signal of the other sensor provided at the other position, for example, it is possible to remove disturbance noise such as geomagnetism applied to both of the magnetic sensor and other magnetic sensor. As described above, since it is possible to remove the disturbance noise without using a cover material or the like for the magnetic sensor, it is possible to detect very small current, and thus it is possible to realize the current measuring device with high sensitivity and high precision.

In the current measuring device according to the aspect of the invention, it is preferable that the calculation unit corrects the distance between the magnetic sensor and the conductor with a predetermined time constant to detect the detection target current. With such a configuration, even when the distance between the magnetic sensor and the conductor is changed, for example, by error of the installation position of the magnetic sensor at the time of producing the current measuring device or thermal expansion of various constituent members of the current measuring device caused by heat emission of the current measuring device, a reference value of the output signal is timely corrected, and thus it is possible to reliably detect the current value flowing in the conductor.

In the current measuring device according to the aspect of the invention, it is preferable that the magnetic sensor is a GMR element.

According to the invention, it is possible to provide the current measuring device capable of correcting the distance between the conductor and the magnetic-electric conversion element and detecting the detection target current with high sensitivity and high precision.

### BRIEF DESCRIPTION OF THE DRAWINGS

FIG. 1 is a diagram illustrating an example of a current measuring device according to a first embodiment of the invention;

FIG. 2A is a diagram illustrating relative positional relation between a magnetic sensor and a conductor in the current measuring device according to the embodiment of the invention;

FIG. 2B is a diagram illustrating correlation between a distance, between a center of a conductor and the magnetic sensor, and intensity of magnetic field detected by the magnetic sensor;

FIG. 3 is a diagram illustrating a calculation process of the current measuring device according to the first embodiment of the invention;

FIG. 4 is a diagram illustrating another example of the current measuring device according to the first embodiment of the invention;

FIG. 5 is a diagram illustrating a current measuring device according to a second embodiment of the invention; and

FIG. 6 is a diagram illustrating a calculation process of the current measuring device according to the second embodiment of the invention.

### DESCRIPTION OF THE PREFERRED EMBODIMENTS

Hereinafter, embodiments of the invention will be described in detail with reference to the accompanying drawings.

### First Embodiment

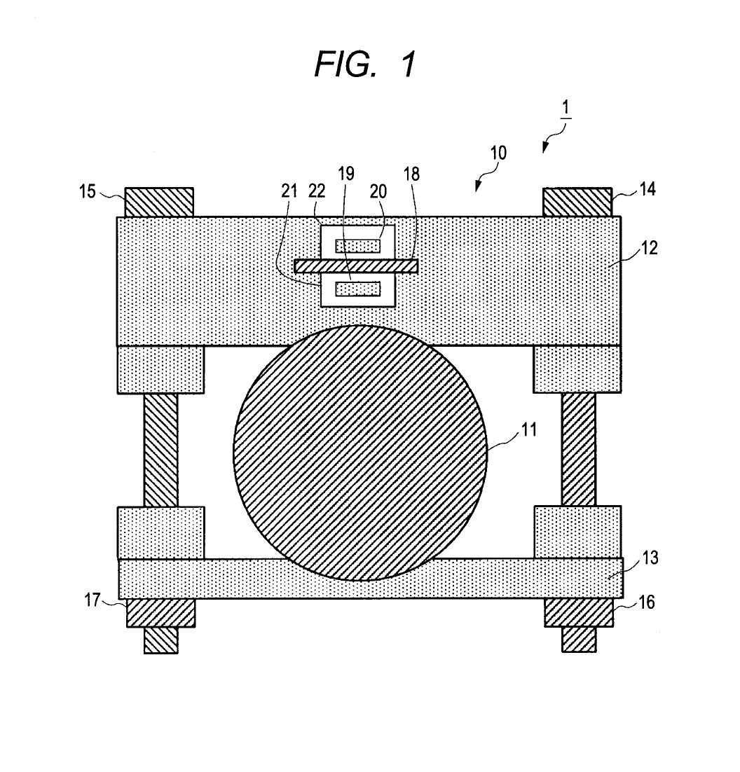

A current measuring device according to the embodiment is provided with a conductor in which detection current flows, and at least two magnetic sensors detecting change of the magnetic field generated when the detection target current flows and outputting a signal. The signal output from the magnetic sensor is subjected to a calculation process by a calculation unit, and both of correction of a distance between the magnetic sensor and the conductor and calculation of the current value flowing in the conductor are performed. Hereinafter, a configuration of the current measuring device according to the embodiment will be described with reference to FIG. 1.

FIG. 1 is a cross-sectional schematic diagram illustrating an example of the current measuring device according to a first embodiment of the invention. As shown in FIG. 1, the current measuring device 1 includes a frame 10, and a conductor 11 which is provided in the frame 10 and in which detection target current flows. The frame 10 includes an upper supporter 12 and a lower supporter 13 pinching the conductor 11 up and down, bolts 14 and 15 and nuts 16 and 17 that are attachment means for tightening the upper supporter 12 and the lower supporter 13 to the conductor 11. The conductor 11 has a circular shape in the cross-sectional view, and extends in a direction of front and back sides of paper. The upper supporter 12 has a width lager than a diameter of the conductor 11, and has through-holes on both sides of the conductor 11. The lower supporter 13 has a shape corresponding to the upper supporter 12, and has through-holes at positions opposed to the through-holes of the upper supporter 12. The bolts 14 and 15 are inserted from the upper supporter 12 side to through-holes of the upper supporter 12 and the lower supporter 13. The lower ends of the bolts 14 and 15 protrude from the lower face of the lower supporter 13, and the nuts 16 and 17 are configured to be tightened to the protruding parts.

A material 18 with a wire and magnetic sensors 19 and 20 detecting current flowing in the conductor 11 are provided in the upper supporter 12. A main face of the material 18 is provided at the center in the upper supporter 12 to be opposed to the center of the conductor 11. A packaging material 21 is provided on the lower main face (conductor 11 side) of the material 18, and the magnetic sensor 19 is sealed in the packaging material 21. A packaging material 22 is provided on the upper main face of the material 18, and the magnetic sensor 20 is provided in the packaging material 22. The magnetic sensors 19 and 20 are provided to detect change of magnetic field generated when current flows in the conductor 11 and to output signals to the calculation unit (not shown) through the wire provided in the material 18. That is, in the embodiment, the magnetic sensors 19 and 20 are provided such that a distance between the conductor 11 and the magnetic sensor 19 is different from a distance between the conductor 11 and the magnetic sensor 20. Since two magnetic sensors 19 and 20 are provided as described above, it is possible to detect change of magnetic field around the conductor 11 generated when current flows in the conductor 11, as different magnetic field intensity.

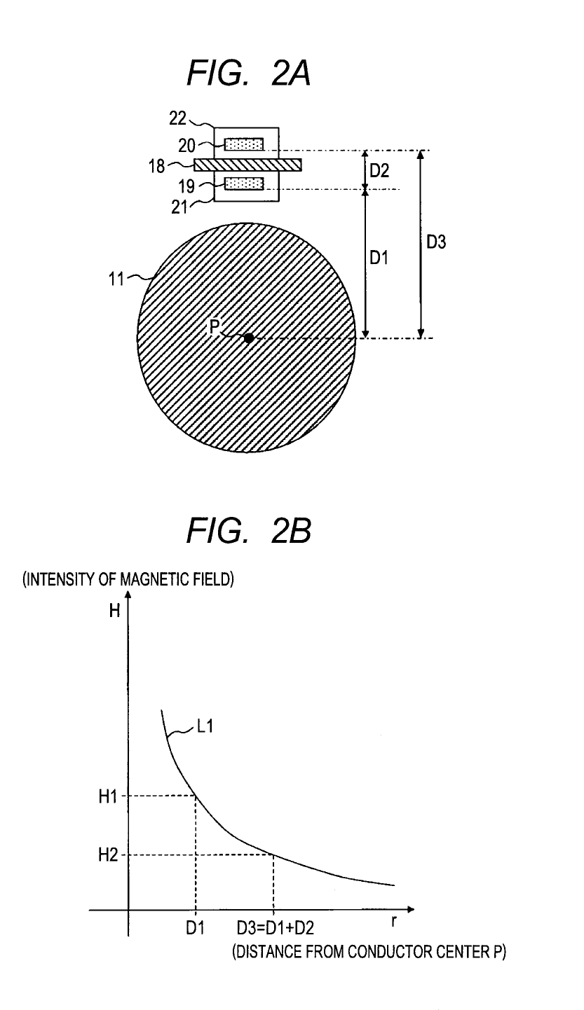

Next, correlation between the distance, between the magnetic sensors 19 and 20 and the conductor 11, and the magnetic field intensity detected by the magnetic sensors 19 and 20 will be described with reference to FIG. 2A and FIG. 2B. FIG. 2A is a schematic diagram illustrating relative positional relation between the conductor 11 and the magnetic sensors 19 and 20 of the current measuring device 1 shown in FIG. 1, and the other constituent members are not shown. FIG. 2B is a diagram illustrating correlation between the distance, between the center P of the conductor 11 and the magnetic sensors 19 and 20, and the magnetic field intensity detected by the magnetic sensor. In FIG. 2B, the distance r between the conductor 11 and the magnetic sensors 19 and 20 is shown in the horizontal axis, and the magnetic field intensity H detected by the magnetic sensors 19 and 20 is shown in the vertical axis.

As shown in FIG. 2A, the magnetic sensor 19 and the center P of the conductor 11 are provided far away at a distance D1, and the magnetic sensor 19 and the magnetic sensor 20 are provided far away at a distance D2 with the material 18 interposed therebetween. The magnetic sensor 20 and the center P of the conductor 11 are provided far away at a distance D3 (D1+D2).

As shown in FIG. 2B, when the same current flows in the conductor 11, magnetic field intensity detected by the magnetic sensor 19 provided far away at the D1 from the center P of the conductor 11 is H1. Magnetic field intensity detected by the magnetic sensor 20 provided far away at the D1+D2 from the center P of the conductor 11 is H2 relatively lower than the H1 detected by the magnetic sensor 19. As described above, in the embodiment, the magnetic field intensity detected by the magnetic sensors 19 and 20 gets lower as the distance from the conductor 11 gets larger.

The inventors thoroughly examined the correlation between the distance, between the center P of the conductor 11 and the magnetic sensors 19 and 20, and the magnitude of the magnetic field intensity detected by the magnetic sensors 19 and 20 described above. As a result, as shown in FIG. 2B by a curve L1, they found that correlation represented by the following formula (1) is satisfied between the distance r, between the center P of the conductor 11 and the magnetic sensors 19 and 20, and the magnetic field intensity H detected by the magnetic sensors 19 and 20.

H=μoI/2πr Formula (1)

In the formula (1), μo indicates vacuum magnetic permeability, H indicates magnetic field intensity detected by the magnetic sensors 19 and 20, r indicates the distance between the center P of the conductor 11 and the magnetic sensors 19 and 20, I indicates the current value flowing in the conductor 11.

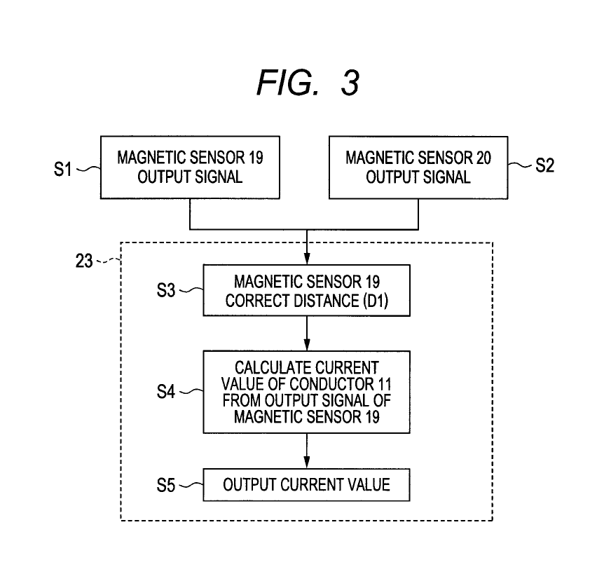

The inventors found that the distance D1 between the magnetic sensor 19 and the center P of the conductor 11 can be corrected in the following formula (4) using the distance D2 between the magnetic sensor 19 and the magnetic sensor 20 set in advance, from an idea that the magnetic field intensity H1 detected by the magnetic sensor 19 becomes the following formula (2) and the magnetic field intensity H2 detected by the magnetic sensor 20 becomes the following formula (3), by the formula (1). The inventors found that it is possible to accurately detect the current value flowing in the conductor 11 by the magnetic sensor 19, by a calculation process of the following formula (5) using the D1 corrected in the formula (4). Hereinafter, a specific example of a signal process using the following formula (2) to the following formula (5) will be described with reference to FIG. 3.

H1=μoI/2πD1 Formula (2)

H2=μoI/2π(D1+D2) Formula (3)

D1=D2(H2/H1−1) Formula (4)

I=2πD1H1/μo Formula (5)

FIG. 3 is a diagram illustrating the signal process of the current measuring device according to the embodiment. As shown in FIG. 3, first, the output signal of the magnetic sensor 19 and the output signal of the magnetic sensor 20 are input to the calculation unit 23 (Step S1 and Step S2). The calculation unit 23 calculates the magnetic field intensity H1 and H2 from the output signals of the magnetic sensor 19 and the magnetic sensor 20, and corrects the distance D1 between the magnetic sensor 19 and the conductor 11 from the formula (4) using the calculated magnetic field intensity H1 and H2 and the value of the D2 set at the time of designing the current measuring device (Step S3). By this calculation process, it is possible to correct the error of the distance between the magnetic sensor 19 and the conductor 11 at the time of producing the current measuring device, and the change of the distance between the magnetic sensor 19 and the conductor 11 in the use condition of the current measuring device.

Then, the current value I flowing in the magnetic sensor 19 is calculated using the corrected distance D1 between the magnetic sensor 19 and the conductor 11 by the formula (5) (Step S4). Then, the calculated current value I is output from the calculation unit 23 (Step S5). As described above, the distance D1 between the magnetic sensor 19 and the center P of the conductor 11 is corrected, and thus it is possible to detect the accurate current value flowing in the conductor 11.

The correction of the distance D1 between the conductor 11 and the magnetic sensor 19 shown in Step S3 of FIG. 3 may be performed at a predetermine time constant (timing) at the time of using the current measuring device 1, and it is not necessary to necessarily perform whenever measuring the current value I. For example, the correction of the distance D1 is performed at the start time of using the current measuring device, then the correction of the distance D1 may not be performed, and the current value may be measured. In a circumstance where the distance D1 is easily changed, the distance D1 may be corrected for each measurement of the current value.

The example shown in FIG. 3 shows an example of the calculation process, and the distance between the magnetic field 20 and the conductor 11 may be corrected to detect the current value flowing in the conductor 11 by the output signal of the magnetic sensor 20.

In the dispositional example shown in FIG. 1, the case of using the circular conductor in the cross-sectional view as the conductor 11 is described, but the same is applied to a case of using a conductor having another shape such as a rectangular shape in the cross-sectional view.

In addition, it is preferable that the magnetic sensors 19 and 20 are provided to overlap in the vertical direction of the main face of the upper supporter 12 in the cross-sectional view of the upper supporter 12 as shown in FIG. 1. As described above, the magnetic sensors 19 and 20 are provided, it is possible to reduce the difference between influences of magnetic field detected by the magnetic sensors 19 and 20, and thus it is possible to reduce the detection error of the magnetic field intensity generated when the current flows in the conductor 11.

In the embodiment, it is preferable to use the magnetic sensor 19 and 20 with substantially the same detection sensitivity. By using the magnetic sensors 19 and 20 with the same detection sensitivity, it is possible to reduce the calculation process and it is easy to calculate the current value flowing in the conductor 11. In the embodiment, the magnetic sensors 19 and 20 with different detection sensitivity may be used. In this case, in the process of the output signals of the magnetic sensors 19 and 20, the detection sensitivity of the magnetic sensors 19 and 20 may be corrected using an amplification circuit corresponding to each detection sensitivity. In this case, it is possible to calculate the current value flowing in the conductor 11 by correcting the curve L1 shown in FIG. 2A according to the detection sensitivity of the magnetic sensors 19 and 20 using the formula (1).

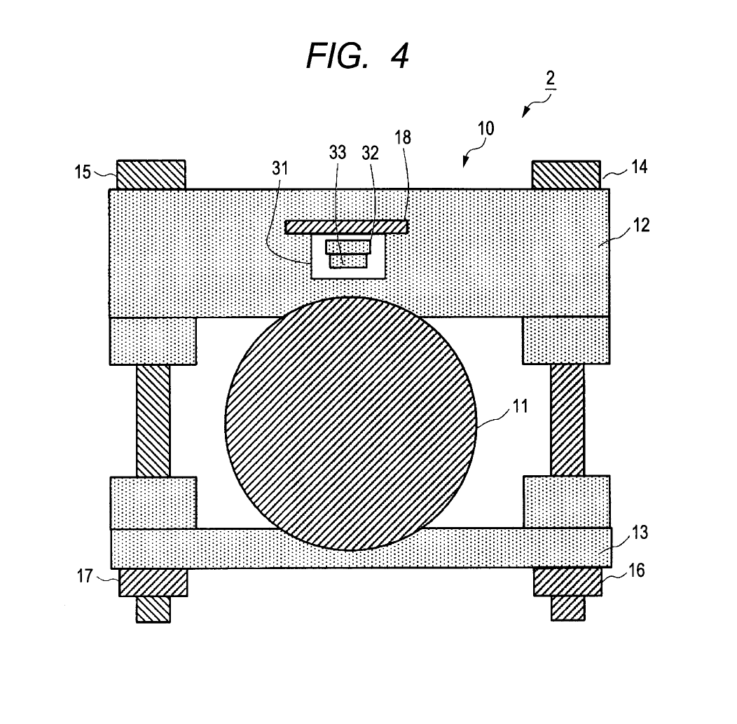

In the current measuring device 1, the disposition of the magnetic sensors 19 and 20 is not particularly limited in the range where the change of the magnetic field generated when the current flows in the conductor 11 can be detected by the other detection sensitivity, and may be disposition different from the example shown in FIG. 1. FIG. 4 shows another example of the current measuring device according to the embodiment. In the current measuring device 2 shown in FIG. 4, magnetic sensors 32 and 33 sealed in the same packaging material 31 are laminated on the main face of the material 18 on the conductor 11 side, in the upper supporter 12. As described above, it is possible to reduce the size of the current measuring device by providing the magnetic sensors 32 and 33 in the same packaging material 31.

A silicon substrate, a glass substrate, or the like may be used as the material 18. A substrate where an insulating film such as silicon oxide is formed on such a substrate may be used.

The magnetic sensors 19 and 20 are not particularly limited when they are magnetic-electric conversion elements having a magnetic-electric conversion effect of converting change of magnetic flux density into resistance or voltage, and a hall element, a hall IC, an MR element, a GMR (Giant Magneto Resistive effect) element, a TMR element, and the like may be used. It is preferable to use the GMR element, the TMR element, or the like having the highest magnetic field sensitivity in a desired direction and having the lowest magnetic field sensitivity in a direction other than the detection target, as the magnetic sensor 19 and 20. A spin valve type GMR element or the like formed of a multilayer having an anti-ferromagnetic layer, a fixed magnetic layer (pinned layer), and a non-magnetic layer, and a free-magnetic layer may be used as the GMR element.

In the embodiment, the bolts 14 and 15 and the nuts 16 and 17 are used as the attachment means, but various members that bond the upper supporter 12 and the lower supporter 13 to the conductor 11 may be used. As a material of the attachment means, various materials having no influence on magnetic field detected by the magnetic sensors 19 and 20 may be used. Particularly, it is preferable to use the non-magnetic material having a small influence on magnetic field formed around the conductor 11.

As described above, according to the embodiment, it is possible to correct the distance D1 between the magnetic sensor 19 and the conductor 11 using the magnetic sensor 19 and the magnetic sensor 20 provided at different distances from the conductor 11. For this reason, even when the distance D1 between the magnetic sensor 19 and the center P of the conductor 11 is changed at the time of producing the current measuring device, it is possible to detect the accurate current value flowing in the conductor 11. Particularly, when high-power current flows in the conductor 11, thermal expansion of the members around the conductor 11 may get larger. However, according to the embodiment, it is possible to detect the accurate current value by correcting the distance D1. Even when the magnetic sensor 19 is provided in the vicinity of the conductor, it is possible to detect the accurate current value.

In the embodiment, even when the conductor 11 is coated, it is possible to correct the distance between the magnetic sensor 19 and the conductor 11 using the output signals of the magnetic sensors 19 and 20. Particularly, when the conductor 11 is coated with a material different from the material of the conductor 11, the change of the distance D1 between the conductor 11 and the magnetic sensor 19 may get larger by thermal expansion or the like. Even in such a case, it is possible to detect the accurate current value.

### Second Embodiment

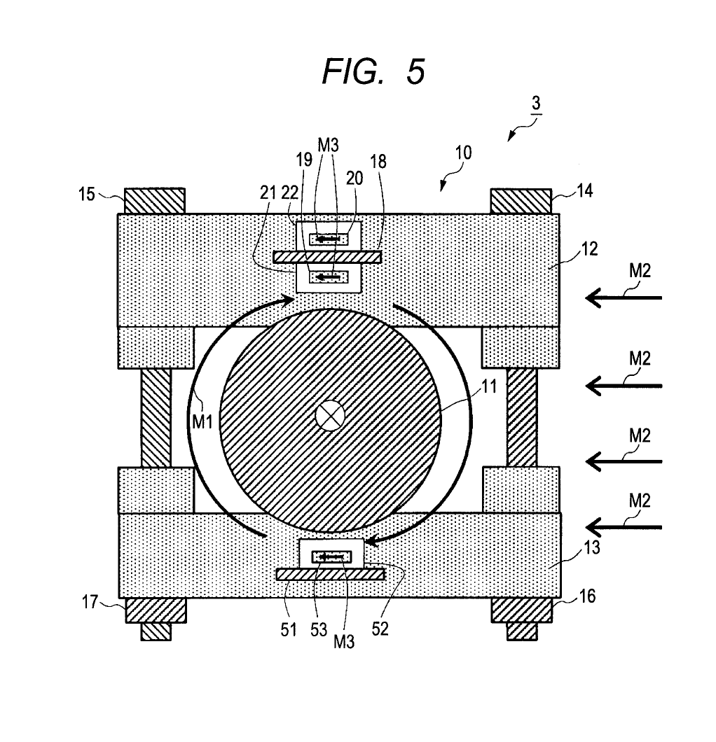

Next, a current measuring device 3 according to a second embodiment of the invention will be described with reference to FIG. 5. The same reference numerals and signs are given to parts having the same configuration as the current measuring device 1 shown in FIG. 1, the description thereof is omitted, and difference from the current measuring device 1 will be mainly described.

As shown in FIG. 5, the current measuring device 3 according to the embodiment is provided with a material 51 having a wire in a lower supporter 13. The material 51 is provided such that a main face thereof is opposed to the center of the conductor 11 at the center in the lower supporter 13. In the upper supporter 12, a magnetic sensor 53 sealed in a packaging material 52 is provided on the main face of the material 51 on the conductor 11 side. The magnetic sensor 53 is provided in the lower supporter 13 such that the distance between the magnetic sensor 53 and the conductor 11 is equal to the distance between the magnetic sensor 19 provided in the upper supporter 12 and the conductor 11. The output signal of the magnetic sensor 53 is output to the calculation unit through the wire of the material 51. That is, in the current measuring device 3, the magnetic sensor 53 is provided in the lower supporter 13 to be opposed to the magnetic sensors 19 and 20 provided in the upper supporter 12 with the conductor 11 interposed therebetween. By providing the magnetic sensor 53 as described above, it is possible to reduce the influence of disturbance noise such as geomagnetism applied to the current measuring device 3 using the output signal of the magnetic sensor 53.

Next, a detection phenomenon of the current measuring device 3 according to the embodiment will be described.

As shown in FIG. 5, when current flows in a direction of front and back sides of paper in the conductor 11, concentric magnetic field M1 having a clockwise direction is generated around the conductor 11 in the plan view. As the magnetic field M1 gets far away from the conductor 11, magnetic field intensity gets lower. The disturbance noise such as geomagnetism is substantially uniformly applied from one direction as shown in the magnetic field M2. As described above, since the disturbance noise such as geomagnetism is substantially uniformly applied in the current measuring device 3, the magnetic field intensity of the disturbance noise detected by the magnetic sensor 19 is substantially equal to that of the disturbance noise detected by the magnetic field sensor 53. For this reason, it is possible to offset an external noise component of the magnetic field intensity detected by the magnetic sensor 19 by calculating the difference value between the output signal of the magnetic sensor 19 and the output signal of the magnetic sensor 53, and thus it is possible to further improve the detection precision of the current flowing in the conductor 11.

As shown in FIG. 5, in the disposition of the magnetic sensors 19, 20, and 53, the axis of easy magnetization (axial direction of sensitivity) may be in the same direction. As described above, when the current flows in the conductor 11, the concentric magnetic field M1 having the clockwise direction is generated around the conductor 11. In the magnetic field M1, the magnetic sensors 19 and 20 provided in the upper supporter 12 are applied in a direction reverse to the magnetic sensor 53 provided in the lower supporter 13. For this reason, when the direction of the axis of easy magnetization M3 of the magnetic sensors 19, 20, and 53 is the same direction, it is possible to detect magnetic field intensity with different phases between the magnetic sensors 19 and 20 and the magnetic sensor 53. As described above, in the current measuring device 3, since it is possible to detect the magnetic field intensity with different phases, it is possible to further improve the detection precision of the current flowing in the conductor 11 using the output signals.

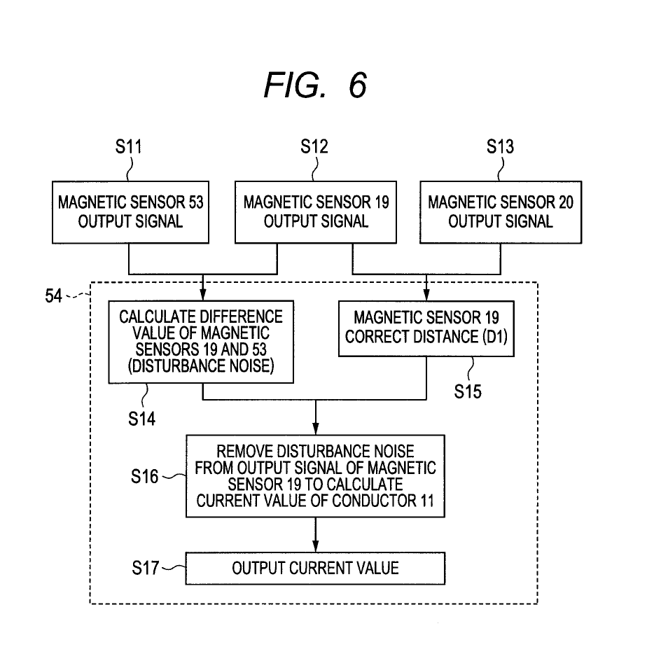

Next, a signal process of the current measuring device 3 according to the embodiment will be described with reference to FIG. 6. In the calculation process shown in FIG. 6, the description of the same calculation process as FIG. 3 is omitted to avoid the repeated description.

As shown in FIG. 6, first, the output signal of the magnetic sensor 19, the output signal of the magnetic sensor 20, and the output signal of the magnetic sensor 53 are input to the calculation unit 54 (Step S11 to Step S13). In the calculation unit 54, the difference value between the output signal of the magnetic sensor 19 and the output signal of the magnetic sensor 53 is detected using the output signal of the magnetic sensor 19 and the output signal of the magnetic sensor 20 (Step S14), and the distance between the magnetic sensor 19 and the conductor 11 is corrected (Step S15).

The disturbance noise component is removed from the output signal of the magnetic sensor 19 using the current value calculated from the output signal of the magnetic sensor 19 after correction and the difference value between the output signal of the magnetic sensor 19 and the output signal of the magnetic sensor 53, and the current value flowing in the conductor 11 is calculated (Step S16). Then, the calculated current value is output from the calculation unit 54 (Step S17). As described above, it is possible to remove the influence of the disturbance noise applied to the current measuring device 3, and it is possible to calculate the accurate current value flowing in the conductor 11.

As described above, according to the embodiment, the magnetic sensors 19 and 20 and the magnetic sensor 53 are opposed with the conductor 11 interposed therebetween, the calculation process is performed using the output signal of the magnetic sensor 53 and the output signal of the magnetic sensor 19, and thus it is possible to remove the influence of the disturbance noise applied to the current measuring device 3. Particularly, in the embodiment, since it is possible to remove the influence of the disturbance noise without using a cover plate such as a shield plate, the detection sensitivity of the current value flowing in the conductor 11 is not decreased. Accordingly, it is possible to realize the current measuring device having the current detection precision with high sensitivity and precision.

Next, examples will be described to clarify the advantages of the invention.

### Example

The current measuring device having the configuration shown in FIG. 1 was produced, and the detection sensitivity of current and measurement error were examined.

A substrate obtained by oxidizing a silicon substrate was used as a substrate material.

A GMR element was used as a magnetic sensor.

### Comparative Example

A current measuring device of the related art as a comparative target was produced, and the detection sensitivity of current and measurement error were examined.

In the configuration of the current measuring device of the related art, one magnetic sensor detecting magnitude of current is provided for one conductor in which current flows.

A substrate obtained by oxidizing a silicon substrate was used as a substrate material.

A GMR element was used as a magnetic sensor.

### Measurement of Current Value

Detection sensitivity was measured under the condition of measuring an output for each 2 A with a current value of 0 to 30 A using the current measuring device produced in Example and Comparative Example. The result is shown in Table 1. In Table 1, as the sensitivity, a comparative value between the current value detected by the current measuring device of Example and the current value detected by the current measuring device of Comparative Example. The error was determined by difference in sensitivity from the current values detected by the current measuring devices of Example and Comparative Example with reference to sensitivity of a current probe of reference connected to a current source.

TABLE 1

| | Example | Comparative Example |
|---|---|---|
| Sensitivity | 1 | 0.3 |
| Error | ±0.0% | ±0.2% |

As shown in Table 1, in the current measuring device used as Example, the detection sensitivity was high, and the detection error was small. On the contrary, in the current measuring device of the related art used as Comparative Example, the detection sensitivity was low, and the detection error was large.

The invention is not limited to the first and second embodiments, and may be variously modified. The materials, the dispositional position of the magnetic sensor, the thickness, the size, and the producing method in the first and the second embodiment may be appropriately modified. In addition, the invention may be modified within the scope of the invention.

The present invention is applicable to a current detecting device and the like, which detects a current value for driving a motor of an electric vehicle or a current value of a solar battery.

It should be understood by those skilled in the art that various modifications, combinations, sub-combinations and alterations may occur depending on design requirements and other factors insofar as they are within the scope of the appended claims of the equivalents thereof.

What is claimed is:

1. A current measuring device comprising:
a conductor in which detection target current flows;
at least two magnetic sensors that detect change of magnetic field generated when the detection target current flows in the conductor; and
a calculation unit that calculates magnitude of the detection target current from an output of the magnetic sensor,
wherein at least two magnetic sensors are provided at different distances from the conductor, and the calculation unit acquires distances between the magnetic sensors and the conductor to calculate magnitude of the detection target current using the distances.

2. The current measuring device according to claim 1, wherein the calculation unit calculates the magnitude of the detection target current by a calculation process based on the following formula (1) using the output of the magnetic sensor:
H=μoI/2πr Formula (1),
where μo indicates vacuum magnetic permeability, H indicates magnetic field intensity, and r indicates a distance between a center P of the conductor and the magnetic sensor.

3. The current measuring device according to claim 1, wherein at least two magnetic sensors are provided in the same package material.

4. The current measuring device according to claim 1, further comprising another magnetic sensor opposed to the magnetic sensor with the conductor interposed therebetween,
wherein the calculation unit detects magnitude of disturbance noise from a difference between an output of the magnetic sensor and an output of the other magnetic sensor and calculates the detection target current using the magnitude of the disturbance noise.

5. The current measuring device according to claim 1, wherein the calculation unit corrects the distance between the magnetic sensor and the conductor with a predetermined time constant to detect the detection target current.

6. The current measuring device according to claim 1, wherein the magnetic sensor is a GMR element.
